(19) United States
(12) Patent Application Publication
(10) Pub. No.: US 2007/0126126 A1
(43) Pub. Date: Jun. 7, 2007

(54) Solder bonding structure using bridge type pattern

(75) Inventors: Seung Gu Kim, Gyeonggi-do (KR); Je Gwang Yoo, Gyeonggi-do (KR); Yong Bin Lee, Chungcheongbuk-do (KR); Yoo Keum Wee, Gyeonggi-do (KR); Seok Hwan Huh, Seoul (KR); Chang Sup Ryu, Gyeonggi-do (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon-si (KR)

(21) Appl. No.: 11/634,221

(22) Filed: Dec. 6, 2006

(30) Foreign Application Priority Data
Dec. 6, 2005 (KR) 10-2005-0118288

(51) Int. Cl. H01L 23/48

(52) U.S. Cl. 257/778

(57) ABSTRACT

Disclosed is a solder bonding structure for flip chip connection. Particularly, this invention relates to a solder bonding structure, in which the shape of a connection pad on which solder is applied is changed to thus increase the size of the solder bond that is formed using a reflow process, resulting in highly reliable solder bonding. To this end, the solder bonding structure is composed of a connection pad (a bridge type pattern) composed of at least two pattern regions spaced apart from each other by a predetermined interval, a solder bond formed on the connection pad having such a shape, and a metal bump in contact with the solder bond. In such a solder bonding structure, the solder bond is formed to a sufficient size on a fine pattern having a smaller width, thus achieving reliable solder bonding between the semiconductor chip having the metal bump and the printed circuit board having the connection pad. Further, since the connection pad may be realized through a typical formation process thereof without the need for an additional process, the reliability of the solder bonding may be sufficiently assured without an increase in the working man-hours or in the number of processes.

### CROSS REFERENCE TO RELATED APPLICATIONS

This application claims the benefit of Korean Patent Application No. 10-2005-0118288, filed Dec. 6, 2005, entitled “Solder bonding structure using a bridge type pattern”, which is hereby incorporated by reference in its entirety into this application.

### BACKGROUND OF THE INVENTION

1. Field of the Invention

The present invention relates, in general, to a solder bonding structure for flip chip connection, and more particularly, to a solder bonding structure, in which the shape of a connection pad on which solder is applied is changed to a bridge type pattern to thus increase the size of a solder bond that is formed using a reflow process, resulting in highly reliable solder bonding.

2. Description of the Related Art

For flip chip mounting of electronic parts such as semiconductor chips, solder in a paste state is applied on the connection pad (i.e., the circuit pattern) of a printed circuit board (PCB), on which a semiconductor chip is mounted, and then undergoes a reflow process to thus form a connection medium such as a solder bond (or a solder ball), followed by performing contact bonding between the PCB and the semiconductor chip having a metal bump, such as a stud bump, using a flip chip bonding process.

Recently, with the increase in the density and degree of integration of semiconductor parts, the sizes of the bump on the semiconductor chip and of the connection pad on the PCB corresponding to the bump are gradually decreasing and narrowing. That is, the increase in the density and degree of integration results in decreased circuit pattern width, and thus the size of the solder bond which is formed on the connection pad is decreased. Consequently, the solder bond is not in sufficient contact with the bump, undesirably causing the problem of decreased reliability of the solder bonding structure.

FIG. 1 is a cross-sectional view illustrating the solder bonding structure according to a conventional example. With reference to this drawing, a solder bonding structure in a poor connection state is described.

As illustrated in FIG. 1, a semiconductor chip 10 having a metal bump 14 protruding between solder resists 12 acting as a protective layer is attached onto a PCB 20 having a connection pad 24 exposed between solder resists 22 using a flip chip bonding process. In this case, while the connection pad 24 on the PCB 20 becomes narrow, the size of the solder bond which is formed on the connection pad is decreased. In some cases, a result in which the metal bump does not contact the solder bond may occur.

That is, assuming that the size of the solder bond, indicated by the dotted line in FIG. 1, is suitable for flip chip bonding, it is difficult to assure the reliability of the bonding structure in which the semiconductor chip 10 having the metal bump is mounted on the PCB 20 having the solder bond 30 formed to be smaller than the above size.

To solve this problem, although the width of the circuit pattern (i.e., the connection pad) may be increased, such an increase undesirably leads to a decrease in the density and degree of integration of the semiconductor part having the solder bonding structure.

Accordingly, the following connection pads have been devised.

FIG. 2 is a plan view illustrating the circuit pattern for solder bonding according to another conventional example. FIG. 2 illustrates a PCB 40, which is characterized in that the width of a connection pad 44 is expanded at a predetermined portion (e.g., a distal portion) thereof. Specifically, as illustrated in FIG. 2, the connection pad 44 exposed between solder resists 42 is composed of a proximal portion 44a and a distal portion 44b, in which the width Wb of the distal portion 44b is larger than the width Wa of the proximal portion 44a.

However, the expansion of the distal portion of the connection pad 44 causes the connection pad to have a result similar to that obtained from a connection pad expanded to the width Wb along the entire length thereof, and thus the amount of solder paste applied over the entire expanded pad becomes greater than the originally intended amount of solder paste, resulting in undesirably increased solder consumption.

FIG. 3 is a cross-sectional view illustrating the circuit pattern for solder bonding according to a further conventional example. In FIG. 3, a PCB 50 comprises not only a connection pad 54 exposed between solder resists 52, but also a bent extension 56 formed around the edge of each of the solder resists 52, in which solder 60 in a paste state is applied on the connection pad 54 and the bent extensions 56.

As above, the formation of the bent extension causes the connection pad to have a result similar to that obtained from a connection pad expanded to a size that includes the bent extension along the entire length thereof, undesirably increasing solder consumption. Furthermore, for the formation of such a structure, since a sequence of applying the solder resist and then forming another pattern (e.g., a bent extension) must be performed, the manufacturing process is complicated and the working time period and working man-hours are also increased.

### SUMMARY OF THE INVENTION

Accordingly, the present invention has been made keeping in mind the above problems occurring in the prior art, and an object of the present invention is to provide a reliable solder bonding structure by forming a solder bond of a sufficient size on a connection pad having a relatively small width.

Another object of the present invention is to provide a semiconductor product having high density and a high degree of integration while assuring the reliability of solder bonding using such a bonding structure.

In order to accomplish the above objects, the present invention provides a solder bonding structure using a bridge type pattern, comprising a semiconductor device having a metal bump; a substrate having a connection pad to which the metal bump is connected and on which the semiconductor device is mounted through bonding between the metal bump and the connection pad; and a solder bond formed on the connection pad to thus realize electrical connection between the metal bump and the connection pad, wherein the connection pad is formed into a bridge type pattern, such that the solder bond is formed to a size sufficient for solder bonding.

In the present invention, the bridge type pattern may comprise at least two pattern regions spaced apart from each other by a predetermined interval.

In addition, in the present invention, the solder bond may be formed using a reflow process, and the predetermined interval may be a distance sufficient for forming a solder paste into a single solder bond on the at least two pattern regions by the reflow process.

In addition, in the present invention, the size of the solder bond is larger than when using a pattern other than the bridge type pattern but having the same line width).

In addition, in the present invention, the semiconductor device may be a flip chip device, and the metal bump may be a stud bump.

### BRIEF DESCRIPTION OF THE DRAWINGS

FIG. 1 is a cross-sectional view showing the solder bonding structure according to a conventional example;

FIG. 2 is a plan view showing the circuit pattern for solder bonding according to another conventional example;

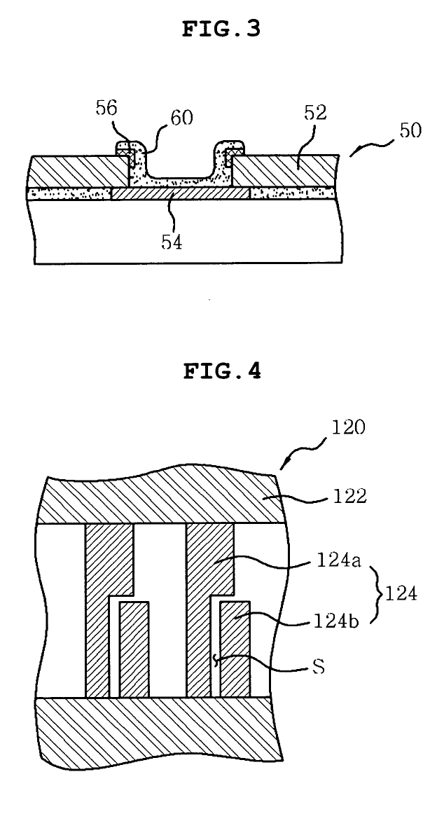

FIG. 3 is a cross-sectional view showing the circuit pattern for solder bonding according to a further conventional example;

FIG. 4 is a plan view showing the circuit pattern for solder bonding according to a first embodiment of the present invention;

FIGS. 5A and 5B are cross-sectional views schematically illustrating the sizes of the solder bonds formed depending on the conventional pattern and the pattern according to the present invention, respectively;

FIG. 6 is a cross-sectional view illustrating the solder bonding structure according to the present invention; and

FIGS. 7A to 7F are plan views illustrating the modifications of the circuit pattern for solder bonding according to a second embodiment of the present invention.

### DESCRIPTION OF THE PREFERRED EMBODIMENTS

Hereinafter, a detailed description will be given of the preferred embodiments of the present invention, with reference to the appended drawings.

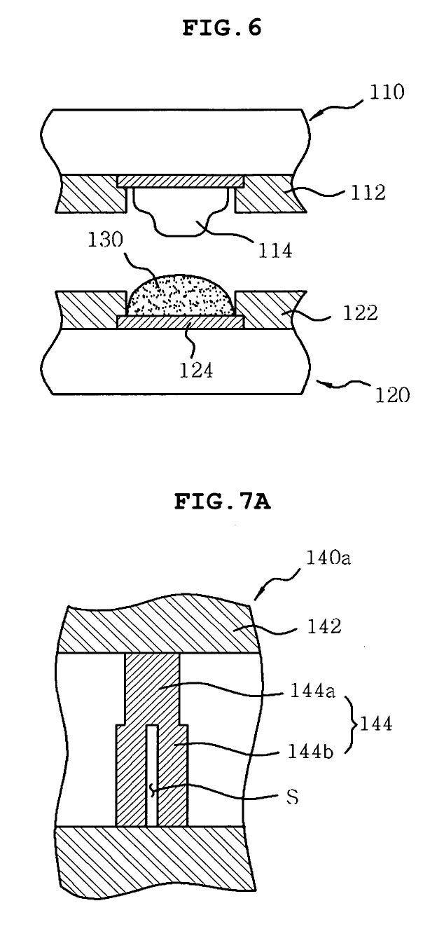

FIG. 4 is a plan view illustrating the circuit pattern for solder bonding, according to a first embodiment of the present invention. As illustrated in FIG. 4, a PCB 120 according to the present invention is characterized in that a connection pad 124 exposed between solder resists 122 is composed of at least two pattern regions 124a, 124b, which are spaced apart from each other by a predetermined interval S. For example, portions of solder paste, which are applied on two separated pattern regions 124a, 124b, swell due to a reflow process and thus agglomerate to each other, consequently forming a single solder bond. This phenomenon is called a “bridging phenomenon”. Herein below, the shape of the connection pad, which aims at the formation of the single solder bond by causing a bridging phenomenon upon formation of the solder bond, is referred to as a “bridge type pattern”.

Accordingly, the bridge type pattern indicates a connection pad composed of at least two pattern regions which are spaced apart from each other. As such, it is preferred that the interval between the pattern regions be maintained at a distance sufficient for forming the single solder bond through agglomeration of the solder (paste) applied on two pattern regions while swelling in the reflow process.

That is, when the interval between the pattern regions is too large, it is impossible to obtain a desired solder bond due to the formation of respective solder bonds on two separated pattern regions. On the other hand, when the interval between the pattern regions is too small, a solder bond cannot be formed to the shape (size) desired in the present invention.

In this way, since the solder bond is formed on the bridge type pattern, based on the sum of the width of separated pattern regions and the interval S between the pattern regions, it may be larger than the solder bond formed based on the size of the pattern regions except for the interval (in the case of a single pattern).

Therefore, a solder bond having a sufficient size may be provided by forming the pattern composed of pattern regions spaced apart from each other by a predetermined interval, in place of forming a larger pattern. Even in the case where a flip chip bonding process is performed using the metal bump which is connected to such a solder bond, a sufficiently reliable connection may be maintained.

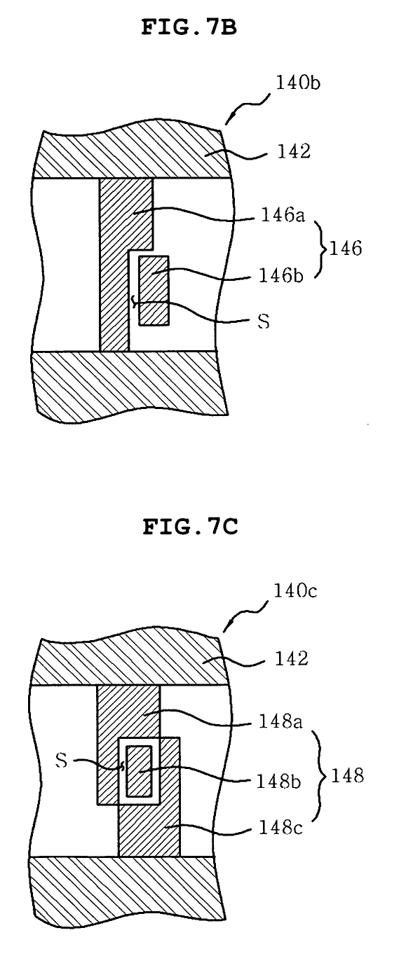

FIGS. 5A and 5B are cross-sectional views schematically illustrating the sizes of the solder bonds formed depending on the conventional pattern and the pattern of the present invention, respectively. With reference to FIGS. 5A and 5B, the conventional connection pad and the connection pad of the present invention are compared.

FIG. 5A illustrates a solder bond 30 formed on a PCB 20 having a conventional connection pad 24, and FIG. 5B illustrates a solder bond 130 formed on a PCB 120 having a connection pad 124 according to the present invention. When the sizes (e.g., heights h₁, h₂) of the solder bonds 30, 130 respectively formed on the conventional connection pad and the connection pad of the present invention are identical, the widths of the connection pads 24, 124 acting as the base thereof may be different.

That is, the conventional connection pad 24 is formed in a single shape having a large width W, and the connection pad 124 of the present invention is composed of two pattern regions 124a, 124b spaced apart from each other by a predetermined interval S. In the present invention, the solder bond 130 may be formed on the connection pad 124 having smaller widths W₁₂₄ₐ, W_{124b} to the same size (height) as the solder bond 30 formed on the pad 24 having the larger width W, by means of a bridging phenomenon.

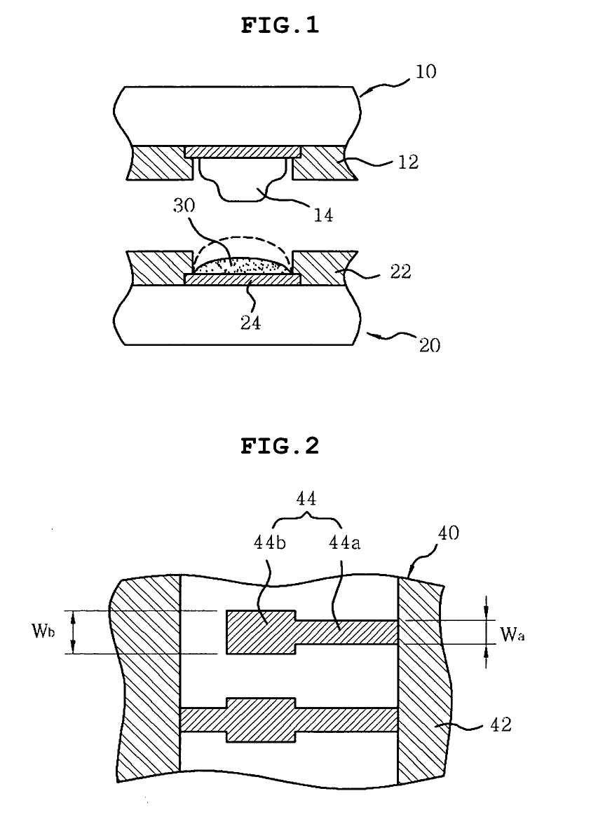

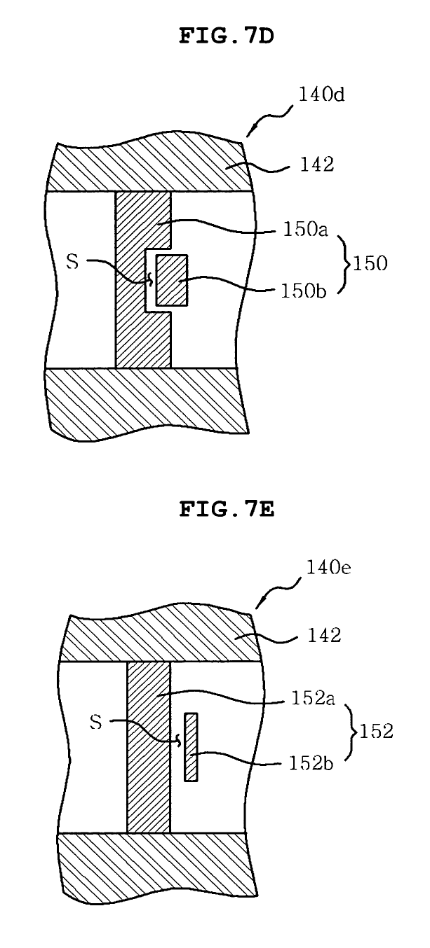

FIG. 6 is a cross-sectional view illustrating the solder bonding structure according to the present invention. In FIG. 6, the flip chip bonding state between a semiconductor device 110 having a metal bump 114 protruding between solder resists 112 and a PCB 120 having a connection pad 124 (having two separated pattern regions) is shown. Unlike the conventional solder bonding structure of FIG. 1, the solder bonding structure according to the present invention is characterized in that the solder bond 130 provided between the solder resists 122 is formed to a sufficient size on the connection pad 124 in the shape of a bridge type pattern (124a, 124b of FIG. 4), and therefore may be reliably connected to the metal bump 114.

In this way, the solder bond having the sufficient size is formed on the connection pad having a smaller width, thereby providing a fine circuit pattern for flip chip semiconductor devices. Consequently, high density and a high degree of integration of semiconductor devices may be easily achieved.

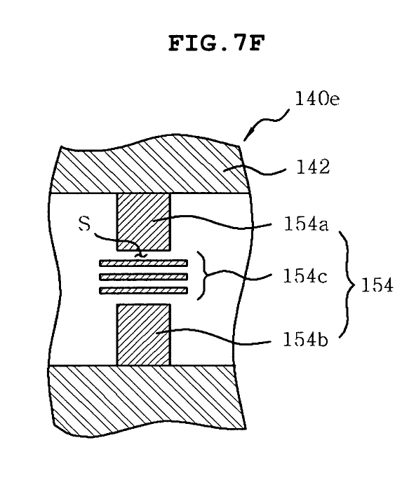

Turning now to FIGS. 7A to 7F, the modifications of the connection pad (i.e., the bridge type pattern) for solder bonding according to a second embodiment of the present invention are illustrated in plan views. Referring to these drawings, various connection pads are provided.

As illustrated in FIGS. 7A to 7F, each of connection pads 144, 146, 148, 150, 152, 154 according to the present invention is exposed between solder resists 142 and is composed of a plurality of pattern regions which are spaced apart from each other by a predetermined interval. After the solder paste is applied on the plurality of pattern regions spaced apart from each other by a predetermined interval, it swells through a reflow process, to thus form the solder bond having a desired size. As such, all the connection pads 144, 146, 148, 150, 152, 154 having the plurality of pattern regions are formed into a fine pattern having a smaller width, compared to conventional connection pads, and the solder applied on the separated pattern regions agglomerates through a bridging phenomenon, thereby forming a single solder bond.

More specifically, when investigated respectively, the connection pad 144 of a PCB 140a of FIG. 7A is composed of a primary pattern region 144a and secondary pattern regions 144b, spaced apart from each other by a predetermined interval S, under the primary pattern region.

The connection pad 146 of a PCB 140b of FIG. 7B is composed of a primary pattern region 146a and a secondary pattern region 146b spaced apart from one side of the primary pattern region by a predetermined interval S.

The connection pad 148 of a PCB 140c of FIG. 7C is composed of two primary pattern regions 148a, 148b and a secondary pattern region 148c separately formed therebetween by a predetermined interval S.

The connection pad 150 of a PCB 140d of FIG. 7D is composed of a primary pattern region 150a and a secondary pattern region 150b spaced apart from one side of the middle portion of the primary pattern region. In this case, the primary pattern region 150a has a recess having a shape complementary to the secondary pattern region 150b.

The connection pad 152 of a PCB 140e of FIG. 7E is composed of a primary pattern region 152a and a secondary pattern region 152b additionally formed at a predetermined distance from one side of the primary pattern region. In this case, the primary pattern region 150a does not have the recess of FIG. 7D.

The connection pad 152 of a PCB 140f of FIG. 7F is composed of two primary pattern regions 154a, 154b and a plurality of secondary pattern regions 154c separately formed in parallel with one another therebetween to thus be spaced apart from each other by a predetermined interval S.

As mentioned above, the solder bonding structure of the present invention may provide the PCB comprising the connection pad (bridge type pattern) composed of at least two pattern regions separated by a predetermined interval. Hence, even though the circuit pattern is formed to a relatively small width, the solder bond having a sufficient size may be formed thanks to a bridging phenomenon occurring between the separated regions, thereby obtaining a sufficiently reliable solder bonding structure.

Further, since the connection pad may be formed using a typical formation process thereof without the need for an additional process, a reliable flip chip bonding process may be performed without an increase in cost or working time period.

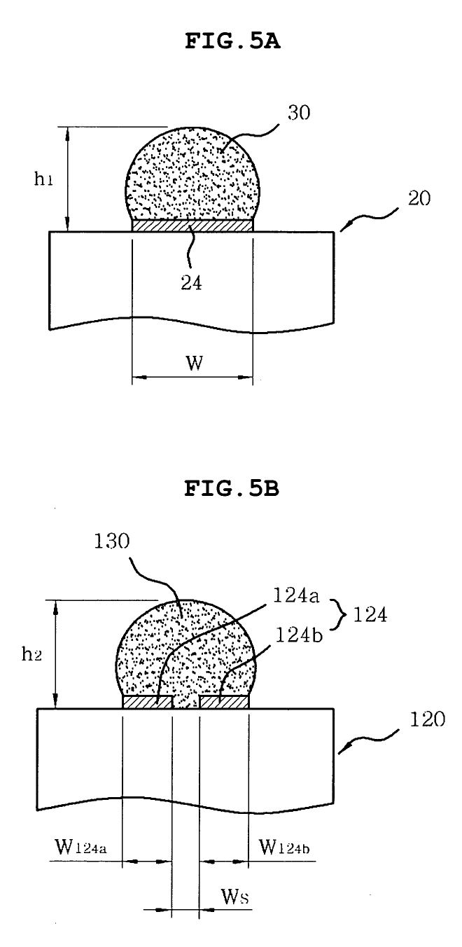

For example, the present invention does not require an additional process for forming a conventional bent extension 56 as illustrated in FIG. 3, that is, a series of applying the solder resist and then forming the pattern for formation of a bent extension. According to the solder bonding structure of the present invention, a typical fine patterning process is applied to thus realize high density and a high degree of integration of semiconductor products and assure sufficient connection reliability.

As described hereinbefore, the present invention provides a solder bonding structure using a bridge type pattern. The solder bonding structure of the present invention comprises a connection pad (in the shape of a bridge type pattern) composed of at least two pattern regions which are spaced apart from each other by a predetermined interval, a solder bond formed on the connection pad having such a shape, and a metal bump in contact with the solder bond. Such a solder bonding structure can make the formation of a solder bond having a sufficient size on a fine pattern having a smaller width possible, thereby realizing reliable solder bonding between the semiconductor chip having the metal bump and the PCB having the connection pad. Further, since the connection pad may be formed using a typical process without the need for an additional process, it is possible to achieve reliable solder bonding without an increase in working man-hours or the number of processes.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A solder bonding structure using a bridge type pattern, comprising:
a semiconductor device having a metal bump;
a substrate having a connection pad to which the metal bump is connected, and on which the semiconductor device is mounted through bonding between the metal bump and the connection pad; and
a solder bond formed on the connection pad to thus realize electrical connection between the metal bump and the connection pad;
wherein the connection pad is formed into a bridge type pattern, such that the solder bond is formed to a size sufficient for solder bonding.

2. The solder bonding structure as set forth in claim 1, wherein the bridge type pattern comprises at least two pattern regions spaced apart from each other by a predetermined interval.

3. The solder bonding structure as set forth in claim 2, wherein the solder bond is formed using a reflow process, and the predetermined interval is a distance sufficient for forming a solder paste into a single solder bond on the at least two pattern regions using the reflow process.

4. The solder bonding structure as set forth in claim 3, wherein a size of the solder bond is larger than when using a pattern other than the bridge type pattern but having the same line width.

5. The solder bonding structure as set forth in claim 1, wherein the semiconductor device is a flip chip device.

6. The solder bonding structure as set forth in claim 5, wherein the metal bump is a stud bump.
